(19) United States
(12) Patent Application Publication
(10) Pub. No.: US 2010/0302075 A1
(43) Pub. Date: Dec. 2, 2010

(54) Keyboard

(75) Inventor: Jack Atzmon, Englewood, NJ (US)

Correspondence Address: COHEN, PONTANI, LIEBERMAN & PAVANE LLP, 551 FIFTH AVENUE, SUITE 1210, NEW YORK, NY, 10176, US

(73) Assignee: Ergowerx International LLC, Englewood, NJ (US)

(21) Appl. No.: 12/811,582

(22) PCT Filed: Jan. 5, 2009
(86) PCT No.: PCT/US09/00024

§ 371 Date: Jul. 2, 2010

Related U.S. Application Data
(60) Provisional application No. 61/018,767, filed on Jan. 3, 2008.

(51) Int. Cl. H03K 17/94

(52) U.S. Cl. 341/22

(57) ABSTRACT

A keyboard includes a drive mechanism. The drive mechanism is configured to drive each of a plurality of keyboard zones to move in a synchronous sequence. The drive mechanism simultaneously tilts and abducts each of the plural keyboard zones.

### CROSS REFERENCE

This application claims priority to U.S. Application No. 61/018,767 filed Jan. 3, 2008, the contents of which is incorporated herein by reference

### BACKGROUND OF THE INVENTION

1. Field of the Invention

The present invention relates to keyboards, and more particularly to an ergonomic keyboard.

2. Description of the Prior Art

A known ergonomic keyboard is split and manually moveable in a tenting motion. This keyboard is not motorized or provided with sensors. It offers no way to guide the user to the best keyboard positions. A manual adjustment mechanism is used so for the user can decide on the best course of treatment. There is no adaptation at all to address repetition a key component to carpal tunnel syndrome and repetitive stress injuries. This type of device still limits needed variation in position and other adaptations for the user that could alleviate or avoid injury. This device also lacks user guidance to optimal positioning and limits adaptation to user only initiated positioning.

Another known ergonomic keyboard does not alter its position at all. There is no attention or adaptation for different sized users, different injuries, or environments. This keyboard fails to address most of the needs of carpal tunnel and repetitive stress injury sufferers. In fact, it does nothing to address the chief cause of carpal tunnel and repetition strain injury, repetition itself.

Another known keyboard has sections that move or pivot in response to use. The sections are all substantially on an underlying surface of the keyboard that elevates towards the middle and towards the outer edges, and descends towards the front. Legs attach the keyboard sections to underlying gears. Multiple gears, and multiple motors, if necessary, allow the sections of the keyboard to move either as a group or individually to each area of the underlying surface.

### SUMMARY OF THE INVENTION

While the foregoing described prior art devices have provided improvement over fixed inflexible work station environments or ordinary flat keyboards, there remains a continuing need in the art for work station environments and apparatuses that provide further attention to the physical needs of the user and which protect the user more substantially against the limited motion and confined motion types of injuries such as carpal tunnel syndrome or repetitive motion syndrome.

An object of the present invention is to provide a keyboard that alters its shape. In particular, the present keyboard includes a drive mechanism that, among other motions, causes keyboard sections to abduct. In contrast to other keyboards that cause the user's hands to pivot, the present keyboard causes the user's hands to abduct.

In one embodiment of the invention, a drive mechanism is provided that allows each of a plurality of keyboard zones to move in a synchronous sequence. The drive mechanism simultaneously tilts and abducts each of the plural keyboard zones. In a preferred embodiment, the drive mechanism includes one motor, however, multiple motors or driving means are used in other embodiments.

### BRIEF DESCRIPTION OF THE DRAWINGS

Further features and advantages of the invention are specified below accompanied by descriptions of exemplary embodiments and with reference to the figures in the drawing. In said drawing:

FIG. 1 is a top view of a keyboard according to an embodiment of the invention in a first position;

FIG. 2 is a top view of a keyboard according to an embodiment of the invention in a second position;

FIG. 3 is a side view of a keyboard according to an embodiment of the invention in a first position;

FIG. 4 is a side view of a keyboard according to an embodiment of the invention in a second position;

FIG. 5 is a top view of a keyboard drive mechanism according to an embodiment of the invention;

FIG. 6 is a side view of a keyboard drive mechanism according to an embodiment of the invention;

FIG. 7 is a side view of a keyboard drive mechanism according to an embodiment of the invention;

FIG. 8 is a side view of a keyboard drive mechanism according to an embodiment of the invention;

FIG. 9 is a top view of a keyboard drive mechanism according to an embodiment of the invention;

FIG. 10 is a bottom view of a keyboard drive mechanism according to an embodiment of the invention; and

FIG. 11 is a front view of a keyboard drive mechanism according to an embodiment of the invention

### DETAILED DESCRIPTION OF THE PREFERRED EMBODIMENTS

FIG. 1 is a top view of a keyboard 100 according to an embodiment of the invention in a first position. As shown, the keyboard has two moveable key sections 20 and 30 in a frame 10. While two keyboard sections are shown, the keyboard can be divided into any number of sections. In one embodiment of the invention, the number pad is a separate section of the keyboard that is configured for independent movement. In one embodiment of the invention, the portions of the key sections 20 and 30 adjacent to frame section 60 are raised with respect to the portions of key sections 20 and 30 distally located from frame section 60. In a preferred embodiment, each key section is a smooth curve or arc.

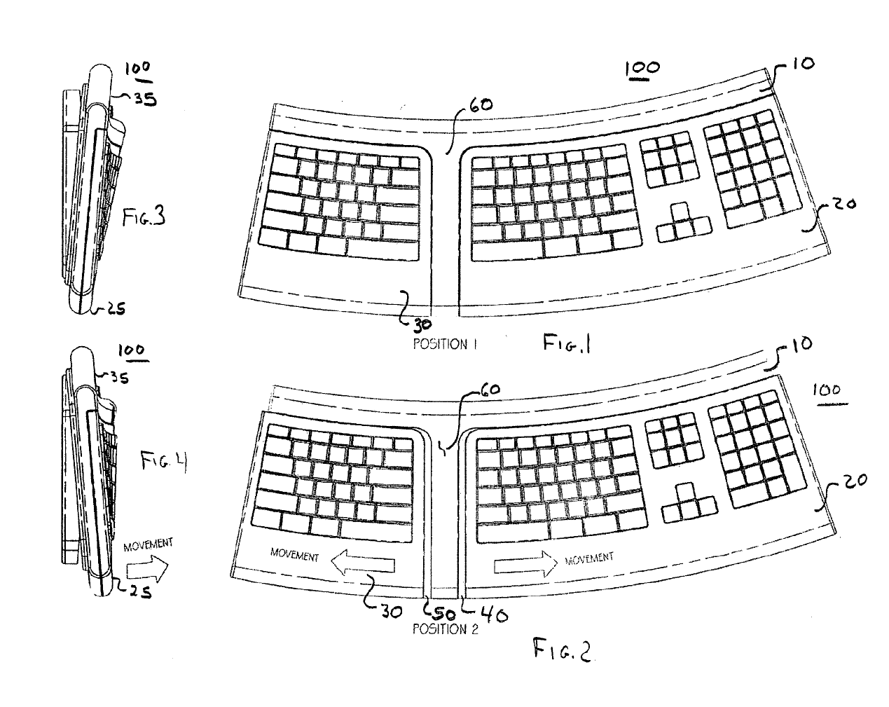

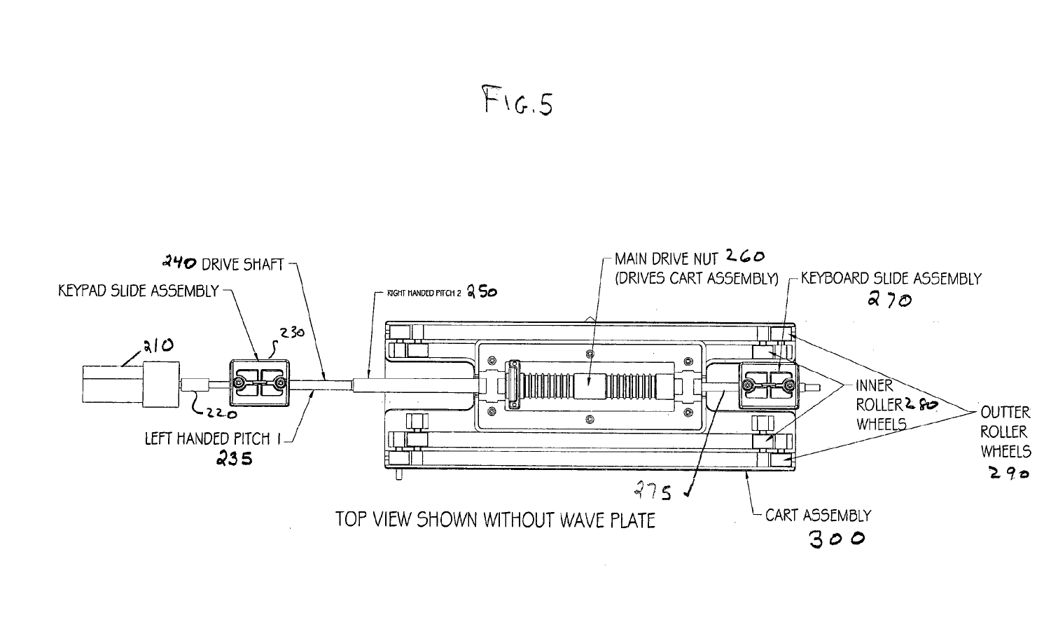

FIG. 2 is a top view of keyboard 100 after moveable key sections 20 and 30 abduct. As shown, each keyboard section 20, 30 moves a distance 40, 50 from central frame segment 60. In one embodiment, the key sections 20 and 30 are substantially in contact with one another without a central frame section 60. In FIG. 2, arrows designate the direction of abduction. It should be noted that key sections 20 and 30 move in a substantially linear manner.

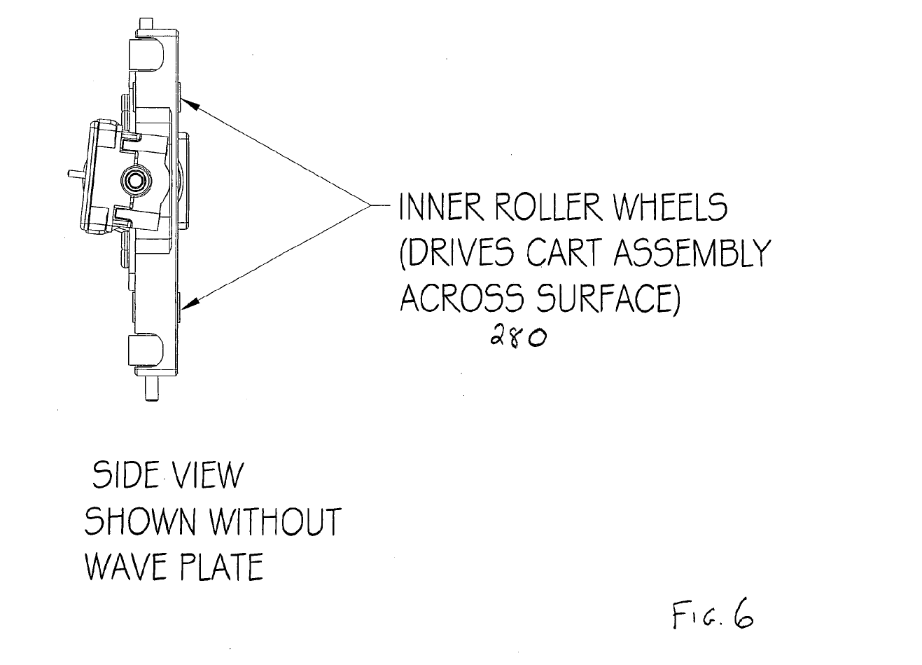

FIGS. 3 and 4 are a side view of the keyboard. FIGS. 3 and 4 depict a pivoting motion of the keyboard 100. As shown, a front edge 25 and a rear edge of the keyboard 35 are configured to seesaw about an axis that is substantially at a midline of the keyboard. In another embodiment, the axis about which the keyboard pivots is located offset from the midline of the keyboard.

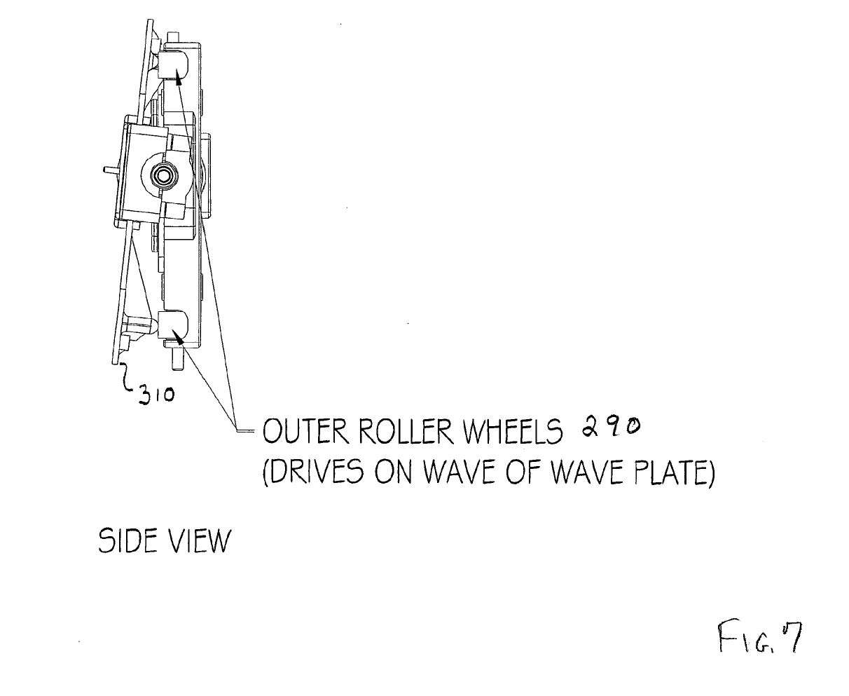

FIG. 5 is a top view of a drive mechanism for the keyboard 100. In one embodiment, the drive mechanism comprises a drive motor 210. The motor 210 is powered via a USB connection, a transformer, batteries, or the like. The motor is shown as a rotary motor. In another embodiment, a linear motor is used. The motor is coupled to a drive shaft via coupler 220. In one embodiment, the coupler 220 is a variable clutch. A first drive shaft 240 is coupled to coupler 220. In a preferred embodiment, the first drive shaft 240 has a left-handed pitch 235.

In one embodiment, a keypad slide assembly 230 rides on the drive shaft. The slide assembly 230 has a coupling nut that rides on the threaded drive shaft so that as the drive shaft rotates, the slide assembly 230 moves laterally along the axis of the drive shaft. Variations in pitch and drive shaft diameter vary the speed of motion.

The drive shaft includes a portion 250 having a right-handed pitch. In one embodiment, the slide assembly moves the keypad and other auxiliary keys and a first keyboard slide assembly (not shown) is mounted on the drive shaft portion 250. A main drive unit 260 is configured to drive the cart assembly. A keyboard slide assembly 270 is mounted on the drive shaft portion 275. As the drive shaft is driven, the keyboard slide assembly 270 is laterally driven along the drive shaft. In a preferred embodiment, the two keyboard slide assemblies are driven in opposite directions due to the opposite thread pitch of their respective drive shaft portions.

Main drive unit 260 drives a cart assembly 300. Inner roller wheels and outer roller wheels are mounted to the cart assembly 300. The roller wheels serve to pivot the keyboard sections as discussed in more detail below. It should be noted that while the motor 210 is shown on one side of the assembly, in other embodiments, a plurality of motors are used. In another embodiment, the motor 210 is oriented at a middle of the assembly and the drive shafts extend laterally in both directions from the center position.

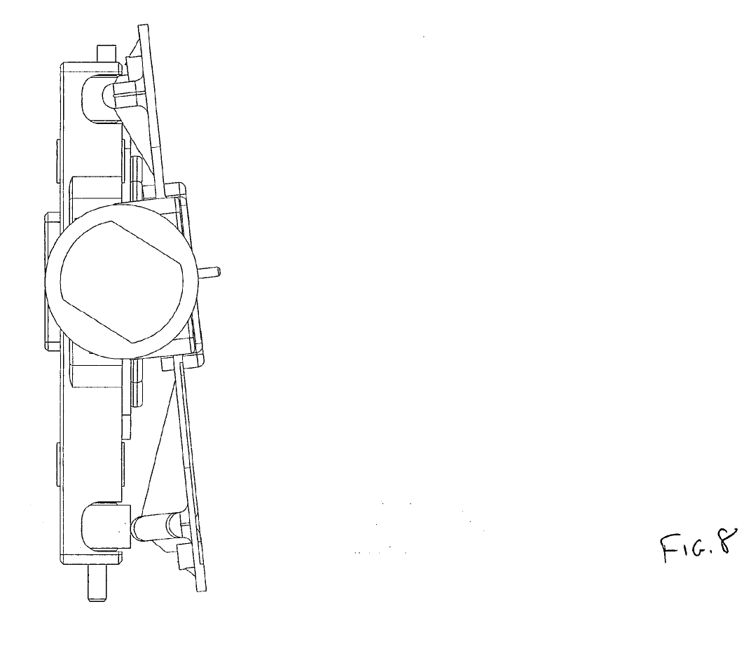

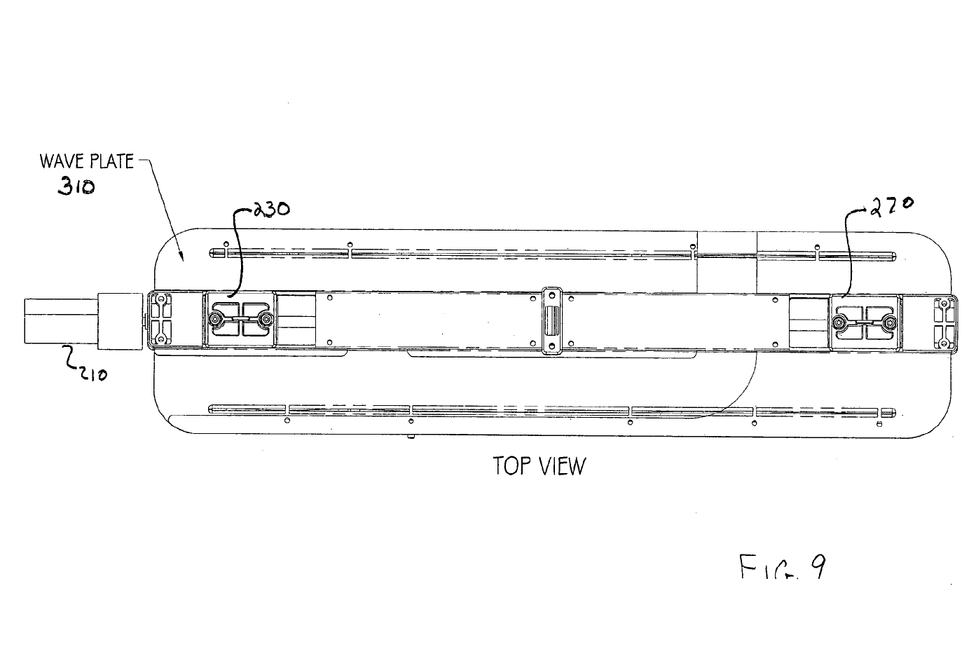

FIG. 6 is a side view of the drive mechanism without the wave plate. As shown, the inner roller wheels 280 drive the cart assembly 300 across a surface. FIG. 7 is a side view of the drive mechanism including wave plate 310. Outer roller wheels 290 ride on wave plate 310. The waves on wave plate 310 are configured to pivot the keyboard sections about an axis substantially corresponding to the drive shaft. FIG. 8 shows the keyboard 100 from the side including motor 210.

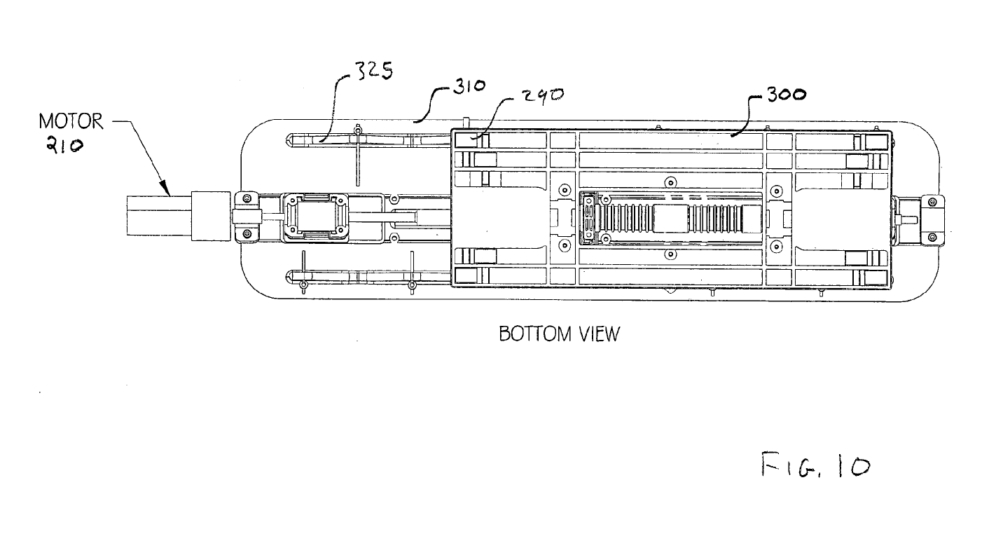

FIG. 9 is a top view of the drive mechanism including wave plate 310. In a preferred embodiment, the slide assembly 230 is couples to key section 20 and slide assembly 270 is coupled to key section 30. In operation, there are two substantially independent movements. The first movement is the driving of the wave plate laterally. The lateral driving of the wave late causes the keyboard portions to pivot. A second motion is the driving of the slide assemblies 230 and 270, which are driven in opposite directions die to the opposite thread pitches.

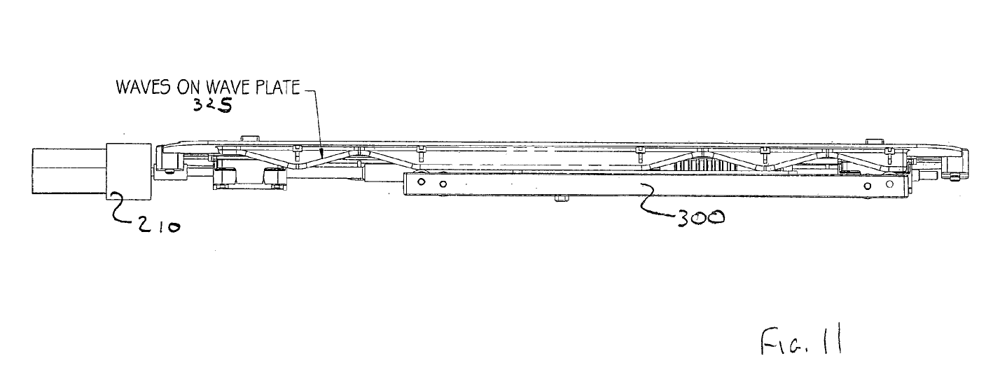

FIG. 10 is a bottom view of the drive mechanism for the keyboard 100. The motor 210 is shown configured to drive the wave plate 310 and the cart 300. The outer wheels 290 are positioned in the cart 300 such that they ride on the waves 325 of the wave plate 310. FIG. 11 is a front view of the drive mechanism showing the cart 300, wave plate 310, and waves 325. It should be noted that in a preferred embodiment, the cart 300 moves laterally with respect to the motor 210 that remains stationary. The key portions pivot due to rollers 290 and waves 325 interacting.

In a preferred embodiment, the drive mechanism is housed in a housing. The housing comprises an upper portion including frame 10 and a base portion. The housing base has preferably has grooves or guides in which rollers 280 of cart 300 roll. The area of the housing configured for the cart to traverse is preferably dust and dirt free. In a preferred embodiment, the keyboard 100 is spillproof to protect the drive mechanism and the electronics associated with the keyboard. In this manner, the cart can be transversely driven to pivot the keyboard portions and without interference from the surrounding environment.

The keyboard is preferably microprocessor controlled. The control can be performed via a PC or an on-board microprocessor. In one embodiment, a computer program running on the user's computer controls the motion. In another embodiment, the program is stored on firmware, onboard the keyboard. In yet another embodiment, the program is stored in flash or other memory that can be updated. Control can also be transmitted from the keyboard or computer using wireless technology. In yet another embodiment, a server on a network such as a local LAN or the Internet controls the keyboard.

The keyboard's movement can be controlled in one of several manners. The keyboard can change its position based on time, amount of use, distance moved temperature, heat, pulse rate, weight, or random motion. Regular rhythmic patterns may also be used to move various portions of the keyboard. Movement may also be based on the program being used or expected keyboard motions. For example, the keyboard can be alerted that a program with heavy side-to-side movement is being used and so that movement may occur more often or with a different pattern.

In one embodiment, the motion is not continuous. In other words, the keyboard will step between positions. The length of time the keyboard remains in any given position will be based at least in part on the above factors.

In one embodiment, the keyboard has a display window (not shown). In one embodiment, the display window is an LCD display. The display can include such items as the specific user, speed setting, motion type, and the like. In one embodiment, the display notifies the user of imminent motion.

In one embodiment of the invention, a user is prompted to use an exercise program based in part on the user's activity. The program will prompt the user to perform tasks to minimize the risk of RSI.

Control software preferably includes, but is not be limited to, programming aimed at relieving or preventing a specific disease such as carpal tunnel or other ailments due to repetitive motion. The gradual movements of the plural keyboard sections substantially eliminate repetitive motion from the same angle thereby improving blood flow, changing position of the median nerve, and resting overworked muscles. The control software preferably stores user information so that a specific user can have a designated motion profile. The control software preferably provides periodic but imperceptible repositioning of the hands and wrists. The reposition provides movement is three axes.

The software programming will preferably monitor repetitive motion on specific keys and adjust the plural keyboard sections accordingly. If a user is constantly focusing on one or a few keys, then the programming will preferably adjust that portion accordingly, moving it more frequently, or various other angles.

The software can be stored on the keyboard itself, the computer or network to which it is attached, a third party computer or a server on the network, a dedicated hardware controller, or on an external source such as a key card or a USB memory card, solid state memory or other storage mechanisms.

In one embodiment, the customization of the software is manipulated by use of pre-programming, settings stored on the computer, server, or by user input. The configuration changes can be made automatically when the user logs on the computer or network. It can also be automatically configured with the help of biometrics or their personal key cards or identification cards. Once the user is identified, the software, wherever it is stored, can adjust the keyboard for that specific user.

In one embodiment, the user can set the keyboard to a preferred position. The keyboard does not vary from that position or, alternatively, the user preset is the starting point for automatic motion.

In another embodiment, at least one of the keyboard and a wrist pad coupled to the keyboard could monitor hand and wrist rest temperature and in addition to the other mentioned adaptations to alleviate common hand and wrist and arm ailments. To that end, at least one of the keyboard and the wrist pad can be heated to warm a user's hands.

While this invention has been described by reference to a preferred embodiment, it should be understood that numerous changes could be made within the spirit and scope of the inventive concepts described. Accordingly, it is intended that the invention not be limited to the disclosed embodiment, but that it have the full scope permitted by the language of the following claims.

What is claimed is:

1. A keyboard comprising:
a plurality of keyboard sections, each of the plural keyboard sections having a plurality of keys; and
a drive mechanism coupled to each of the plural keyboard sections, the drive mechanism configured to abduct the plural keyboard sections.

2. The keyboard according to claim 1 further comprising a wave plate coupled to the plural keyboard sections, the wave plate configured to pivot the plural keyboard sections about a first axis transverse to a direction of abduction.

3. The keyboard according to claim 2, wherein each of the plural keyboard sections is pivoted synchronously.

4. The keyboard according to claim 2, wherein each of the plural keyboard sections is pivoted asynchronously.

5. The keyboard according to claim 1, further comprising a motor coupled to the plural keyboard sections, the motor configured to drive the drive mechanism.

6. The keyboard according to claim 2, wherein the wave plate is coupled to the drive mechanism.

7. The keyboard according to claim 1, wherein the plural keyboard sections abduct laterally in substantially equal amounts from a centerline.

8. The keyboard according to claim 2, further comprising a plurality of roller wheels coupled to each of the plural keyboard sections, the plural roller wheel configured to traverse the wave plate to thereby pivoting the plural keyboard sections.

9. The keyboard according to claim 1, wherein the drive mechanism further comprises a drive shaft having a first thread coupled to a first of the plural keyboard sections and a second thread coupled to another of the plural keyboard sections, wherein one of the first and the second thread is right handed and the other of the first and the second thread is left handed.

10. The keyboard according to claim 2, wherein the drive mechanism further comprises a drive shaft having a first thread coupled to a first of the plural keyboard sections and a second thread coupled to another of the plural keyboard sections, wherein one of the first and the second thread is right handed and the other of the first and the second thread is left handed.

11. The keyboard according to claim 10, wherein the drive mechanism further comprises a drive shaft having a third section coupled to the wave plate, the third section configured to move the wave plate laterally.

12. The keyboard according to claim 2, wherein the drive mechanism further comprises a drive shaft having a fourth section coupled to a keypad side assembly, the fourth section configured to abduct the keypad side assembly.

13. The keyboard according to claim 2, wherein the wave plate is configured to pivot the keypad side assembly.

14. The keyboard according to claim 2, further comprising a heater configured to heat at least one of the plural keyboard sections and a wrist rest coupled to the keyboard.

15. A method of operating a keyboard, the keyboard comprising a plurality of keyboard sections and a drive mechanism configured to abduct the plural keyboard sections, the method comprising:
monitoring parameters including at least one of button presses, time, and keyboard section position;
activating the drive mechanism based on the parameters, the drive mechanism abducting a position of the plural keyboard sections.

16. The method of operating the keyboard according to claim 15, further comprising pivoting the plural keyboard sections about an axis transverse to the direction of abduction.
